(19) United States
(12) Patent Application Publication
(10) Pub. No.: US 2026/0003286 A1
(43) Pub. Date: Jan. 1, 2026

(54) RESIST TOPCOAT COMPOSITION AND METHOD OF FORMING PATTERNS USING THE COMPOSITION

(71) Applicant: SAMSUNG SDI CO., LTD., Yongin-si (KR)

(72) Inventors: Ran NAMGUNG, Suwon-si (KR); Hyeon PARK, Suwon-si (KR); Daeseok SONG, Suwon-si (KR); Kyoungjin HA, Suwon-si (KR); Minsoo KIM, Suwon-si (KR)

(21) Appl. No.: 19/173,599

(22) Filed: Apr. 8, 2025

(30) Foreign Application Priority Data
Jun. 27, 2024 (KR) 10-2024-0084740

(51) Int. Cl. G03F 7/11; C09D 7/20; C09D 133/16; G03F 7/16

(52) U.S. Cl. CPC G03F 7/11; C09D 7/20; C09D 133/16; G03F 7/168

(57) ABSTRACT

Provided are a resist topcoat composition and a method of forming patterns using the resist topcoat composition, the resist topcoat composition including a polymer including a first structural unit and a second structural unit; and a solvent, wherein the first structural unit is represented by Chemical Formula M-1, and the second structural unit includes a metal element and is derived from a compound having an unsaturated double bond. Details of the Chemical Formulas are as described in the specification.

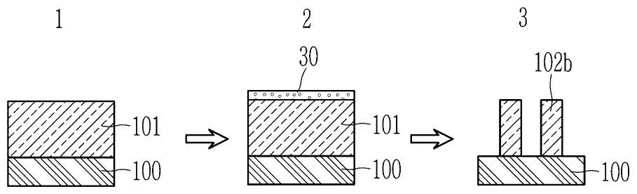

### CROSS-REFERENCE TO RELATED APPLICATION

The present application claims priority to and the benefit of Korean Patent Application No. 10-2024-0084740 filed in the Korean Intellectual Property Office on Jun. 27, 2024, the entire content of which is hereby incorporated by reference.

### BACKGROUND

### 1. Field

Embodiments of this disclosure relate to a resist topcoat composition, and a method of forming patterns using the same.

### 2. Description of the Related Art

Recently, the semiconductor industry has developed an ultrafine technique having a pattern of several to several tens nanometer size. Such ultrafine technique would benefit from effective photolithographic processes.

Photolithographic processes may involve forming a material layer on a semiconductor substrate, coating a photoresist layer thereon, exposing and developing the photoresist layer to form a photoresist pattern, and then etching the material layer using the photoresist pattern as a mask.

As photolithography processes develop, a degree of pattern integration is increasing, and materials and technologies for solving various problems occurring in this process would be beneficial.

For example, if (e.g., when) extreme ultra violet light (EUV) is irradiated to the photoresist, because there may be a region where a large amount of light or a small amount of light is randomly irradiated due to the large energy per photon, which may be referred to as a photo shot noise, or an EUV absorption difference between upper and lower portions of the photoresist may cause pattern distribution deterioration such as roughness (e.g., LER: line edge roughness, LWR: line width roughness) and/or IPU (in-point uniformity) of the patterns, in order to improve this pattern distribution deterioration, technology development would be beneficial.

### SUMMARY

Some example embodiments of the present disclosure provide a resist topcoat composition which not only prevents or reduces pattern degradation and reduces pattern distribution degradation, but also improves sensitivity.

Some example embodiments provide a method of forming patterns using the resist topcoat composition.

Some example embodiments provide a resist topcoat composition including a polymer including a first structural unit and a second structural unit; and a solvent, wherein the first structural unit is represented by Chemical Formula M-1, and the second structural unit includes a metal element and is derived from a compound having an unsaturated double bond (e.g., is formed from a compound including a metal element and an unsaturated double bond).

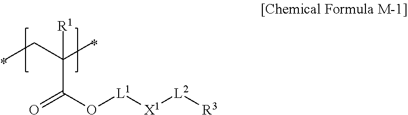

In Chemical Formula M-1,
R¹ is hydrogen or a substituted or unsubstituted C1 to C10 alkyl group,
L¹ and L² are each independently a single bond (e.g., a single covalent bond), a substituted or unsubstituted C1 to C10 alkylene group, or a combination thereof,
X¹ is a single bond (e.g., a single covalent bond), —O—, —S—, —S(═O)—, —S(═O)₂—, —C(═O)—, —C(═O)O—, —OC(═O), —OC(═O)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
at least one selected from among R³, L¹, and L² includes fluorine and a hydroxy group, and
* is a linking point.

Some example embodiments provide a method of forming patterns which includes coating and heating a photoresist composition on a substrate to form a photoresist layer, coating and heating the aforementioned resist topcoat composition on the photoresist layer to form a topcoat, and exposing and developing the topcoat and the photoresist layer to form a resist pattern.

The resist topcoat composition according to some example embodiments, if (e.g., when) exposed to EUV, improves sensitivity due to the presence of Sb, Sn, and/or Te, which have high EUV absorption efficiency and concurrently (e.g., simultaneously), prevents or reduces pattern roughness (LER, LWR) generated due to high photon energy of EUV or pattern distribution degradation of IPU and/or the like and accordingly, may be advantageously used to form a fine photoresist pattern.

### BRIEF DESCRIPTION OF THE DRAWING

The accompanying drawing, together with the specification, illustrates embodiments of the subject matter of the present disclosure, and, together with the description, serves to explain principles of embodiments of the subject matter of the present disclosure.

The accompanying drawing is a schematic cross-sectional view illustrating a method of forming patterns using a resist topcoat composition according to some example embodiments.

### DETAILED DESCRIPTION

Hereinafter, embodiments of the present disclosure will be described in more detail so that those skilled in the art can easily implement the subject matter of the present disclosure. However, the subject matter of this disclosure may be embodied in many different forms and should not be construed as limited to the example embodiments set forth herein.

In the accompanying drawing, the thickness of layers, films, panels, regions, etc., may be exaggerated for clarity and like reference numerals designate like elements throughout the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

As used herein, if (e.g., when) a definition is not otherwise provided, the term “substituted” refers to replacement of a hydrogen atom of a compound by a substituent selected from a halogen atom (F, Br, Cl, or I), a hydroxy group, a thiol group, a nitro group, a cyano group, an amino group, a substituted or unsubstituted C1 to C30 amine group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C30 sulfide group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, if (e.g., when) a definition is not otherwise provided, the term “an alkyl group” refers to a linear or branched aliphatic hydrocarbon group. The alkyl group may be “a saturated alkyl group” that does not include any double bond or triple bond.

The alkyl group may be a C1 to C20 alkyl group. In some embodiments, the alkyl group may be a C1 to C10 alkyl group or a C1 to C6 alkyl group. For example, the term C1 to C5 alkyl group may mean that the alkyl chain contains 1 to 5 carbon atoms and is selected from methyl, ethyl, propyl, iso-propyl, n-butyl, iso-butyl, sec-butyl, and tert-butyl.

The term alkyl group may refers to examples that include a methyl group, an ethyl group, a propyl group, an isopropyl group, a butyl group, an isobutyl group, a tert-butyl group, a pentyl group, a hexyl group, and the like.

In chemical formulas described herein, t-Bu refers to a tert-butyl group.

As used herein, if (e.g., when) a definition is not otherwise provided, the term “cycloalkyl group” refers to a monovalent cyclic aliphatic hydrocarbon group.

The term “cycloalkyl group” refers to a cyclopropyl group, a cyclobutyl group, a cyclopentyl group, a cyclohexyl group, and the like.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but is not limited thereto.

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

As used herein, the term “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms).

As used herein, if (e.g., when) a definition is not otherwise provided, the term “hetero” refers to one including 1 to 3 heteroatoms selected from N, O, S, Se, and P.

In the present disclosure, if (e.g., when) a definition is not otherwise provided, the term “heterocycloalkyl group” refers to a cycloalkyl group including at least one hetero atom selected from N, O, S, P, and Si.

In embodiments of the present disclosure, the term “heteroaryl group” refers to an aryl group including at least one hetero atom selected from N, O, S, P, and Si. Two or more heteroaryl groups may be linked by a sigma bond directly, or if (e.g., when) the heteroaryl group includes two or more rings, the two or more rings may be fused. If (e.g., when) the heteroaryl group is a fused ring, each ring may include 1 to 3 hetero atoms.

Unless otherwise specified in the present specification, the weight average molecular weight may be measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

Unless otherwise defined in the specification, “*” indicates a linking point of a structural unit or a compound moiety of a compound.

Hereinafter, a resist topcoat composition according to some example embodiments is described.

The described technology relates generally to a photoresist topcoat composition and a method of forming a photoresist pattern using the topcoat, which can improve sensitivity of the photoresist during the photolithography micropattern formation process using high-energy rays such as EUV (extreme ultraviolet light; e.g., having a wavelength of 13.5 nm) and at the same time can selectively reduce an acid concentration in the upper layer of the photoresist, to improve IPU (in-point uniformity) of C/H (contact hole) patterns, LER (line edge roughness)/LWR (line width roughness) of L/S (line and space) patterns, and/or IPU of pillar patterns.

A resist topcoat composition according to some example embodiments includes a polymer including a first structural unit represented by Chemical Formula M-1, and a second structural unit derived from a compound including a metal element and having an unsaturated double bond (e.g., is formed from a compound including a metal element and an unsaturated double bond); and a solvent.

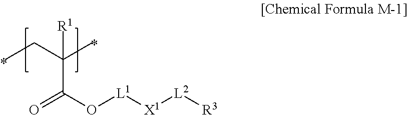

In Chemical Formula M-1,
R¹ is hydrogen or a substituted or unsubstituted C1 to C10 alkyl group,
L¹ and L² are each independently a single bond (e.g., a single covalent bond), a substituted or unsubstituted C1 to C10 alkylene group, or a combination thereof,
X¹ is a single bond (e.g., a single covalent bond), —O—, —S—, —S(═O)—, —S(═O)₂—, —C(═O)—, —C(═O)O—, —OC(═O), —OC(═O)O—, —NR^{a}— (wherein, R^{a} is hydrogen, deuterium, or a substituted or unsubstituted C1 to C10 alkyl group), or a combination thereof,
R³ is hydrogen, fluorine, a hydroxy group, a substituted or unsubstituted C1 to C20 alkyl group, or a combination thereof,
at least one selected from among R³, L¹, and L² includes fluorine and a hydroxy group, and
* is a linking point.

If (e.g., when) a photoresist is patterned by exposure with EUV, the high energy of EUV photons may cause a photo shot noise, which may result in pattern roughness (LER, LWR) and/or pattern distribution degradation of IPU and/or the like.

The photoresist topcoat composition according to some example embodiments may not only be suppressed or reduced from the pattern distribution degradation through reduction of the photo shot noise but also increase sensitivity by introducing a metal element having a high EUV absorption rate into a polymer.

In some embodiments, the polymer, which includes a fluoro and hydroxy group-containing structural unit that can be well dissolved in a solvent with almost no reactivity with the photoresist (e.g., may have little to no reactivity with the photoresist), may protect the photoresist but minimally affect the photoresist (or have a reduced effect on the photoresist), and may be easy to remove due to its characteristics of being well dissolved in the solvent.

In some embodiments, the photoresist topcoat composition according to embodiments of the present disclosure is coated on the top of the photoresist layer to significantly improve LER/LWR of L/S patterns, IPU of C/H patterns, and IPU of Pillar patterns and also improve sensitivity.

In some embodiments, the first structural unit may be represented by Chemical Formula 1.

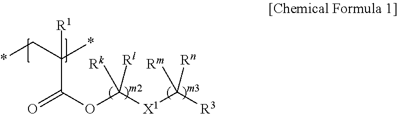

In Chemical Formula 1,
R¹ is hydrogen or a substituted or unsubstituted C1 to C10 alkyl group,
R^{k}, R^{l}, R^{m}, Rⁿ, and R³ are each independently hydrogen, fluorine, a hydroxy group, a substituted or unsubstituted C1 to C20 alkyl group, or a combination thereof,
m2 and m3 are each independently an integer from 1 to 10,
X¹ is a single bond (e.g., a single covalent bond), —O—, —S—, —S(═O)—, —S(═O)₂—, —C(═O)—, —C(═O)O—, —OC(═O), —OC(═O)O—, —NR^{a}— (wherein, R^{a} is hydrogen, deuterium, or a substituted or unsubstituted C1 to C10 alkyl group), or a combination thereof, and
at least one selected from R^{k}, R^{l}, R^{m}, Rⁿ, and R³ includes fluorine and a hydroxy group.

In Chemical Formula 1, if (e.g., when) m2 is 2 or more, each R^{k} may be the same or different from each other.

In Chemical Formula 1, if (e.g., when) m2 is 2 or more, each R^{l} may be the same or different from each other.

In Chemical Formula 1, if (e.g., when) m3 is 2 or more, each R^{m} may be the same or different from each other.

In Chemical Formula 1, if (e.g., when) m3 is 2 or more, each Rⁿ may be the same or different from each other.

In Chemical Formula 1, the meaning that at least one selected from among R^{k}, R^{l}, R^{m}, Rⁿ, and R³ includes a fluorine and hydroxy group may include cases where:
at least one selected from among R^{k}, R^{l}, R^{m}, Rⁿ, and R³ is each independently a fluorine and hydroxy group, or
at least one selected from among R^{k}, R^{l}, R^{m}, Rⁿ, and R³ each independently includes a C1 to C10 alkyl group substituted with one or more fluorine and a C1 to C10 alkyl group substituted with one or more hydroxy groups, or
at least one selected from among R^{k}, R^{l}, R^{m}, Rⁿ, and R³ each independently includes one or more hydroxy groups and one or more C1 to C10 alkyl groups substituted with fluorine, or
at least one selected from among R^{k}, R^{l}, R^{m}, Rⁿ, and R³ each independently includes a C1 to C5 alkyl group substituted with one or more hydroxy groups and one or more C1 to C5 fluoroalkyl groups, or
at least one selected from among R^{k}, R^{l}, R^{m}, Rⁿ, and R³ is fluorine, and at least one of the others selected from among R^{k}, R^{l}, R^{m}, Rⁿ, and R³ is a hydroxy group, or
at least one selected from among R^{k}, R^{l}, R^{m}, Rⁿ, and R³ is fluorine, and at least one of the others selected from among R^{k}, R^{l}, R^{m}, Rⁿ, and R³ includes a C1 to C10 alkyl group substituted with one or more hydroxy groups, or
at least one selected from among R^{k}, R^{l}, R^{m}, Rⁿ, and R³ is a hydroxy group, and at least one of the others selected from among R^{k}, R^{l}, R^{m}, Rⁿ, and R³ includes a C1 to C10 alkyl group substituted with one or more fluorines, or
at least one selected from among R^{k}, R^{l}, R^{m}, Rⁿ, and R³ is a C1 to C20 alkyl group substituted with one or more fluorine, and at least one of the others selected from among R^{k}, R^{l}, R^{m}, Rⁿ, and R³ is a C1 to C20 alkyl group substituted with one or more hydroxy groups.

For example, R¹ may be hydrogen or a methyl group,
X¹ may be a single bond (e.g., a single covalent bond), —O—, or —NR^{a}— (wherein, R^{a} is hydrogen, deuterium, or a substituted or unsubstituted C1 to C10 alkyl group), and
R³ may be fluorine, a hydroxy group, a C1 to C10 alkyl group substituted with at least one fluorine, or a C1 to C10 alkyl group substituted with at least one hydroxy group.

As an example, in Chemical Formula 1, at least one selected from among R^{m}, Rⁿ, and R³ may include a fluorine and a hydroxy group.

As an example, in Chemical Formula 1, at least one selected from among R^{m} and Rⁿ may be fluorine or a C1 to C10 alkyl group substituted with at least one fluorine, and R³ may be a hydroxy group or a C1 to C10 alkyl group substituted with at least one hydroxy group.

As an example, in Chemical Formula 1, at least one selected from among R^{m} and Rⁿ may be a hydroxy group or a C1 to C10 alkyl group substituted with at least one hydroxy group, and R³ may be fluorine or a C1 to C10 alkyl group substituted with at least one fluorine.

As an example, in Chemical Formula 1, R^{m} may be a hydroxy group or a C1 to C10 alkyl group substituted with at least one hydroxy group, Rⁿ may be fluorine or a C1 to C10 alkyl group substituted with at least one fluorine, and R³ may be a hydroxy group, fluorine, or a C1 to C10 alkyl group substituted with at least one of fluorine and hydroxy groups.

As an example, in Chemical Formula 1, at least one selected from among R^{m} and Rⁿ may be fluorine or a C1 to C10 alkyl group substituted with at least one fluorine, and R³ may be a hydroxy group or a C1 to C5 alkyl group substituted with at least one of a hydroxy group and a C1 to C5 fluoroalkyl group.

For example, the first structural unit may be selected from Group I.

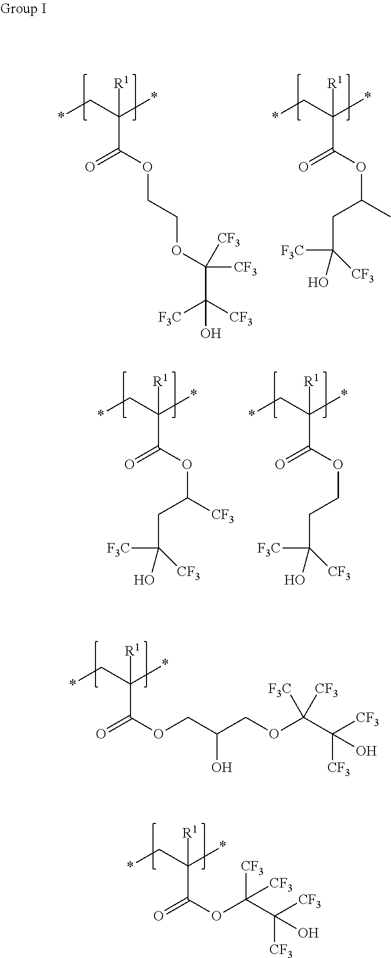

In Group I,
R¹ is each independently hydrogen or a methyl group, and * is a linking point.

In some embodiments, the metal element included in the second structural unit may be at least one selected from Sb, Sn, and Te.

For example, the second structural unit may be derived from (e.g., formed from) a compound represented by Chemical Formula 2 or Chemical Formula 3.

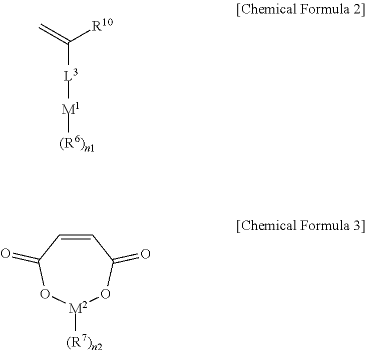

In Chemical Formula 2 and Chemical Formula 3,
R¹⁰ is hydrogen or a substituted or unsubstituted C1 to C10 alkyl group,
M¹ is Sn, Sb, or Te,
M² is Sn or Sb,
L³ is a single bond (e.g., a single covalent bond), a substituted or unsubstituted C1 to C10 alkylene group, a substituted or unsubstituted C6 to C20 arylene group, or a combination thereof,
R⁶ and R⁷ are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C6 to C20 aryl group, OR^{b}, or OC(═O)R^{c} (wherein, R^{b} and R^{c} are each independently a substituted or unsubstituted C1 to C10 alkyl group),
n1 is an integer from 1 to 3,
n2 is an integer of 1 or 2, and
if (e.g., when) n1 is 2 or greater, each R⁶ may be the same or different from each other.

If (e.g., when) n2 is 2 or greater, each R⁷ can be the same or different.

In some example embodiments, the second structural unit may be derived from (e.g., formed from) at least one compound selected from the group listed in Group II.

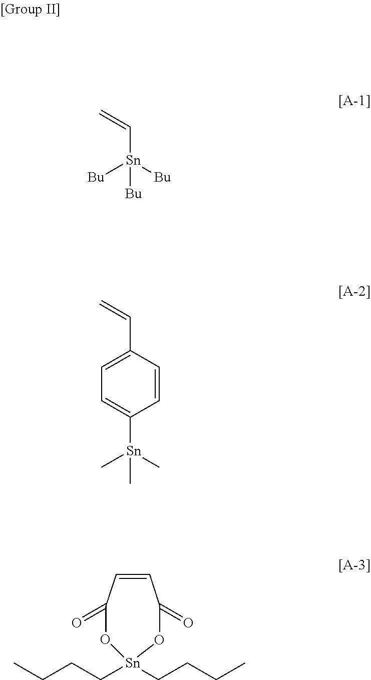

The polymer may further include an additional structural unit represented by Chemical Formula M-2.

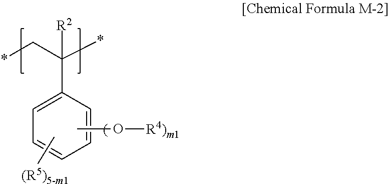

In Chemical Formula M-2,
R² is hydrogen or a substituted or unsubstituted C1 to C10 alkyl group,
R⁴ is hydrogen, or C(═O)R^{d},
R^{d} is a substituted or unsubstituted C1 to C10 alkyl group,
R⁵ is hydrogen, a halogen, a hydroxy group, a substituted or unsubstituted C1 to C10 alkyl group, or a combination thereof,
m1 is an integer from 1 to 4, and
* is a linking point.

In Chemical Formula M-2, if (e.g., when) m1 is 2 or greater, each O—R⁴ may be the same or different from each other.

In Chemical Formula M-2, if (e.g., when) 5-m1 is 2 or greater, each R⁵ may be the same or different from each other.

As an example, the additional structural unit may be represented by any one selected from among Chemical Formula 4-1 to Chemical Formula 4-4.

### [Chemical Formula 4-1] [Chemical Formula 4-2] [Chemical Formula 4-3] [Chemical

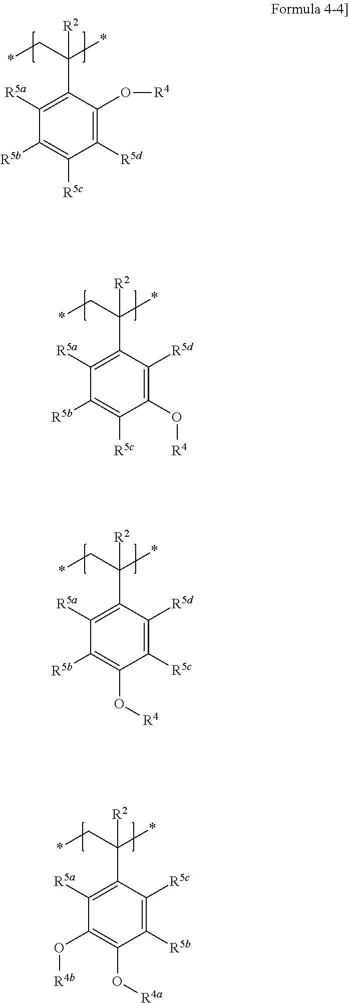

In Chemical Formula 4-1 to Chemical Formula 4-4,
R² is hydrogen or a methyl group,
R⁴, R^{4a}, and R^{4b} are each independently hydrogen, or C(═O)R^{b},
R^{b} is a substituted or unsubstituted C1 to C5 alkyl group,
R^{5a}, R^{5b}, R^{5c}, and R^{5d} are each independently hydrogen, a halogen, a hydroxy group, a substituted or unsubstituted C1 to C10 alkyl group, or a combination thereof, and
* is a linking point.

For example, at least one R⁵ may be a halogen.

As an example, at least one R⁵ may be an iodine group.

Sensitivity can be further improved by including an iodine group in the additional structural unit.

For example, the additional structural unit may be selected from the groups in Group III.

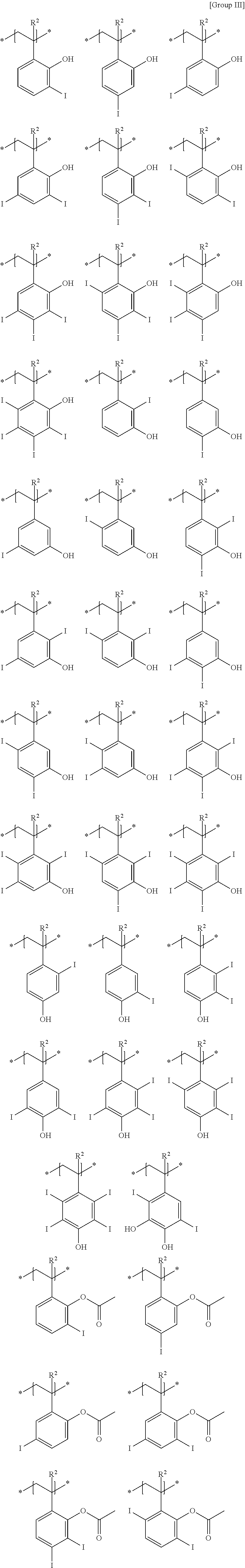

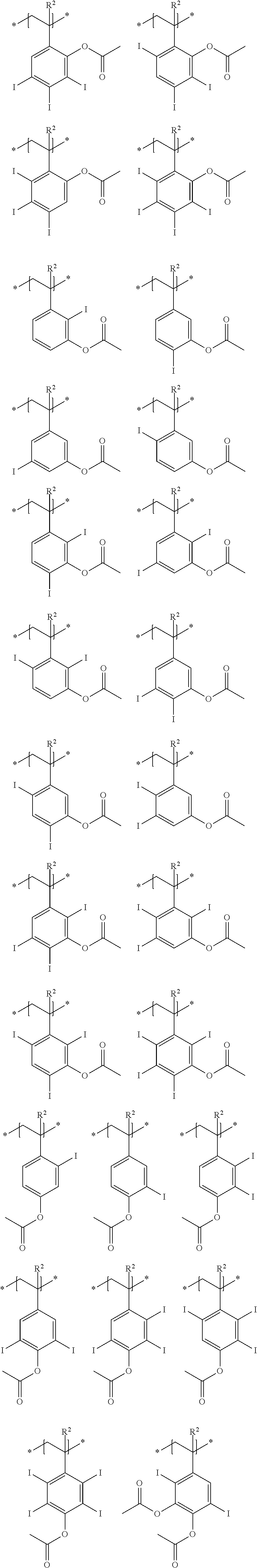

In Group III,
R² are each independently hydrogen or a methyl group, and * is a linking point.

The polymer may include about 50 to about 99 mol % of the first structural unit, and about 1 to about 50 mol % of the second structural unit.

For example, the polymer may include about 70 to about 99 mol % of the first structural unit, about 1 to about 30 mol % of the second structural unit, for example, about 70 to about 90 mol % of the first structural unit, and about 10 to about 30 mol % of the second structural unit. In some embodiments, the polymer may include about 75 to about 95 mol % of the first structural unit and about 5 to about 25 mol % of the second structural unit.

If (e.g., when) the molar ratio of each structural unit included in the polymer is within the above ranges, the solubility in organic solvents is improved and the pattern can be uniformly (e.g., substantially uniformly) coated.

The polymer may have a weight average molecular weight (Mw) of about 1,000 g/mol to about 50,000 g/mol. For example, the polymer may have a weight average molecular weight of about 2,000 g/mol to about 30,000 g/mol, for example, about 3,000 g/mol to about 20,000 g/mol, or for example about 4,000 g/mol to about 10,000 g/mol, but is not limited thereto. If (e.g., when) the weight average molecular weight of the polymer is within the above ranges, a carbon content and solubility in a solvent of the resist topcoat composition including the polymer may be optimized or improved.

The polymer may be included in an amount of about 0.1 wt % to about 10 wt % based on a total weight of the resist topcoat composition.

For example, it may be included in an amount of about 0.1 wt % to about 5 wt %, for example, about 0.1 wt % to about 3 wt %, based on a total weight of the resist topcoat composition.

Within the above ranges, the resist topcoat may be easily removed.

In some example embodiments, the polymer (e.g., a copolymer) may be selected from those listed in Group IV.

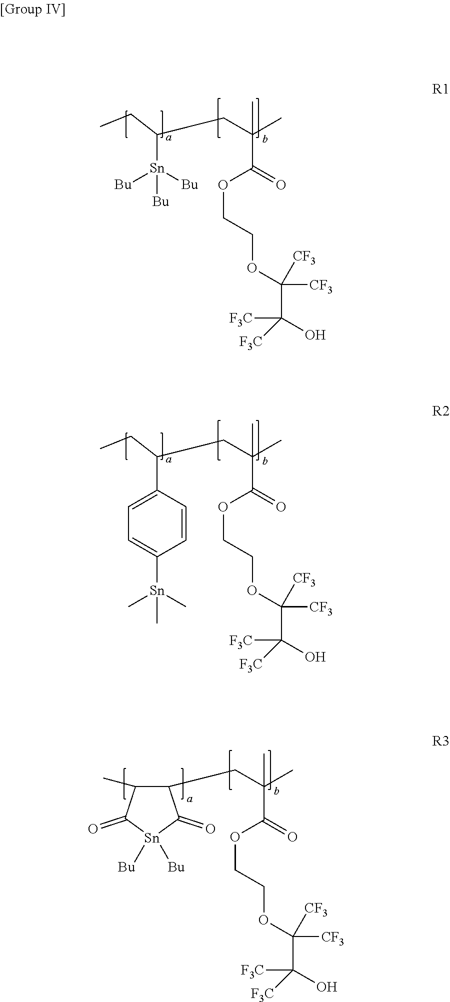

In Group IV, a ratio of a:b may be about 99:1 to about 70:30, for example, about 90:10 to about 70:30, or about 95:5 to about 75:25.

In some embodiments, the resist topcoat composition may further include at least one other polymer selected from an epoxy-based resin, a novolac resin, a glycoluril-based resin, and a melamine-based resin, but the present disclosure is not limited thereto.

The resist topcoat composition may further include an additive including a surfactant, a thermal acid generator, a plasticizer, or a combination thereof.

The surfactant may be, for example, an alkylbenzene sulfonic acid salt, an alkylpyridinium salt, polyethylene glycol, a quaternary ammonium salt, and/or the like, but is not limited thereto.

The thermal acid generator may be, for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, naphthalene carboxylic acid and/or benzoin tosylate, 2-nitrobenzyl tosylate, and/or other organic sulfonic acid alkyl esters, but is not limited thereto.

The amount of these additives used can be easily adjusted according to suitable or desired physical properties and may be omitted.

The solvent may be an ether-based solvent, and may be, for example, represented by Chemical Formula 5.

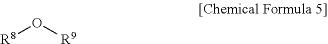

In Chemical Formula 9,
R⁸ and R⁹ are each independently a substituted or unsubstituted C1 to C20 alkyl group, or a substituted or unsubstituted C3 to C30 cycloalkyl group.

For example, the ether-based solvent may be selected from diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, and a combination thereof.

The ether-based solvent may have suitable or sufficient solubility and/or dispersibility for the aforementioned composition.

According to some example embodiments, a method of forming patterns using the aforementioned photoresist topcoat composition may be provided. For example, the manufactured pattern may be a photoresist pattern.

A method of forming patterns according to some example embodiments includes coating and heating a photoresist composition on a substrate to form a photoresist layer, coating and heating the aforementioned photoresist topcoat composition on the photoresist layer to form a topcoat, and exposing and developing the topcoat and the photoresist layer to form a resist pattern.

Hereinafter, a method of forming patterns using the aforementioned photoresist topcoat composition will be described with reference to the accompanying drawing. The accompanying drawing is a schematic cross-sectional view illustrating a method of forming patterns using a photoresist topcoat composition according to embodiments of the present disclosure.

Referring to the accompanying drawing, first, an object 100 to be etched is prepared. An example of the object to be etched may be a thin film on a semiconductor substrate. Hereinafter, only embodiments where the object to be etched is a thin film will be described, but the present disclosure is not limited thereto. The surface of the thin film is cleaned to remove contaminants remaining on the thin film. The thin film may be, for example, a silicon nitride film, a polysilicon film, and/or a silicon oxide film.

A photoresist composition is coated on the thin film and heated to form a photoresist layer 101 (Act 1). Subsequently, the photoresist topcoat composition is coated on the photoresist layer and heated to form a photoresist topcoat 30 (Act 2).

The heating may be performed at a temperature of about 80° C. to about 500° C.

Then, the photoresist topcoat and the photoresist layer are exposed to high-energy radiation.

For example, the high-energy radiation that can be used in the exposure process may include light having a high-energy wavelength, such as EUV (Extreme Ultraviolet; wavelength: 13.5 nm) and/or E-Beam (electron beam).

A post-exposure heat treatment (PEB) is then performed. The post-exposure heat treatment may be performed at a temperature of about 80° C. to about 200° C. By performing the post-exposure heat treatment, the exposed region of the photoresist layer, for example, the region not covered by the patterned mask is changed to a property that is soluble in a developer, so that the exposed region has a different solubility from that of the unexposed region of the photoresist layer.

A photoresist pattern 102b may be formed by dissolving and removing the photoresist layer corresponding to the exposed region and the photoresist topcoat using a developer (Act 3).

In some embodiments, the developer may be an alkaline developer and/or a developer containing an organic solvent (hereinafter referred to as an organic developer).

As the alkaline developer, a quaternary ammonium salt such as tetramethylammonium hydroxide may be used, but aqueous alkaline solutions such as inorganic alkalis, primary to tertiary amines, alcohol amines, and/or cyclic amines may also be used.

In some embodiments, the alkaline developer may include an alcohol and/or a surfactant in a suitable or appropriate amount. An alkaline concentration of the alkaline developer may be, for example, about 0.1 to about 20 mass %, and a pH of the alkaline developer may be, for example, about 10 to about 15.

The organic developer may be a developer including at least one organic solvent selected from the group consisting of ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and the like.

Examples of the ester solvent may include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and the like.

Any suitable solvents may be used as alcohol solvents, amide solvents, ether solvents, and/or hydrocarbon solvents.

A plurality of said solvents may be mixed, or may be mixed with solvents or water other than the above-described solvents. A moisture content as a whole of the developer may be suitably or desirably less than about 50 wt %, more suitably or desirably less than about 20 wt %, suitably or desirably less than about 10 wt %, or, for example, the developer may be substantially free of moisture.

A content of the organic solvent may be suitably or desirably about 50 to about 100 wt %, suitably or desirably about 80 to about 100 wt %, suitably or desirably about 90 to about 100 wt %, or, for example, suitably or desirably about 95 to about 100 wt % based on a total amount of the organic developer.

The organic developer may include a suitable or appropriate amount of any suitable surfactant as required or desired.

A content of the surfactant may be about 0.001 to about 5 wt %, suitably or desirably about 0.005 to about 2 wt %, or, for example, suitably or desirably about 0.01 to about 0.5 wt % based on a total amount of the developer.

The organic developer may include the aforementioned inhibitor.

Subsequently, the exposed thin film is etched by applying the photoresist pattern as an etching mask. As a result, the thin film is formed into a thin film pattern.

The thin film may be etched, for example, by dry etching using an etching gas, and the etching gas may be, for example, CHF₃, CF₄, Cl₂, BCl₃, and/or a mixture thereof.

In the exposure process performed above, the thin film pattern formed using the photoresist pattern that is formed by the exposure process performed using the EUV light source may have a width corresponding to the photoresist pattern. For example, the photoresist pattern may have a width of about 5 nm to about 100 nm. For example, the thin film pattern formed by the exposure process performed using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, and may have a width of less than or equal to about 20 nm, for example, like the photoresist pattern.

Hereinafter, embodiments of the present disclosure will be described in more detail through examples relating to the synthesis of embodiments of the aforementioned polymer and the preparation of a photoresist topcoat composition including the same. However, the present disclosure is not technically limited by the following examples.

### SYNTHESIS EXAMPLES

### (Synthesis of Polymer)

### Synthesis Example 1: Synthesis of Compound 1a

20 g of hexafluoro-2,3-bis(trifluoromethyl)-2,3-butanediol(perfluoropinacol), 7.79 g of 2-(hydroxyethyl)methacrylate, and 18.84 g of triphenylphosphine (PH₃P) were mixed in 110 ml of diethylether under a nitrogen atmosphere and then, stirred. After stirring for 30 minutes, the mixture was cooled down to 0° C., and another mixture of 14.52 g of diisopropyl azodicarboxylate (DIAD) and 35 ml of diethylether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by using silica gel to separate a synthesized material. The separated material was distilled under a reduced pressure, thereby obtaining 2-[3,3,3-trifluoro-2-hydroxy-1,1,2-tris(trifluoromethyl)propoxy]ethyl 2-methyl-2-propenoate represented by Chemical Formula 1a.

* ¹H-NMR (Acetone-d6): δ 1.90 (3H, t), 4.36 (4H, m), 5.63 (1H, t), 6.09 (1H, t), 8.34 (1H, s)

* ¹⁹F-NMR (Acetone-d6): δ −70.12 (6F, m), −65.38 (6F, m)

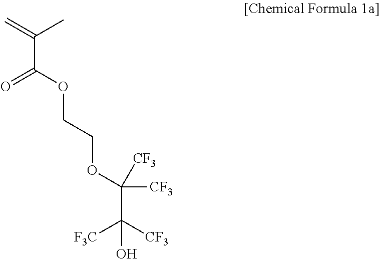 [SMILES: C=C(C)C(=O)OCCOC(C(F)(F)F)(C(F)(F)F)C(O)(C(F)(F)F)C(F)(F)F]

### Synthesis Example 2: Preparation of Polymer R1

In a 250 mL 2-neck round bottom flask, 10.7 g of the compound represented by Chemical Formula 1a, 1.9 g of the compound represented by Chemical Formula 1b (tributylvinyltin, TCI T1794) and 40 g of diisoamyl ether (DIAE) were added under a nitrogen atmosphere, and then heated so that the internal temperature reached 85° C. When the internal temperature reached 85° C., 14.7 g of 25 wt % V-601/DIAE solution (3.7 g of V-601) was slowly added thereto, and after 6 hours of reaction, the resultant mixture was cooled to room temperature and concentrated to 50% of a solid content. 250 g of heptane was added to the concentrated solution, and a polymer produced therefrom was filtered. The filtered polymer was completely dissolved in 34 g of DIAE, and 250 g of heptane was added thereto for precipitation, which were twice repeated to obtain precipitates, and the precipitates were completely dried, thereby preparing a final polymer (R1, Mw=4,500, a:b=81:19) having a structure of Chemical Formula 1-1.

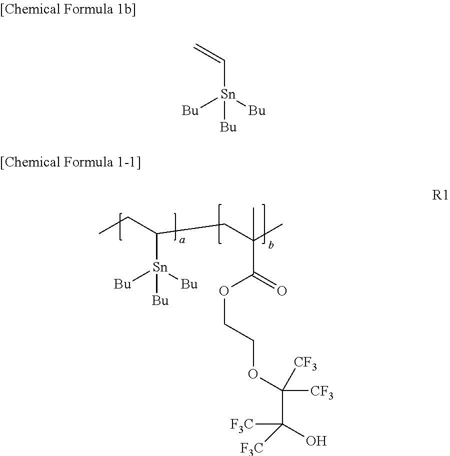

### Synthesis Example 3: Preparation of Polymer R2

A polymer (R2, Mw=5,300, a:b=80:20) having a structure represented by Chemical Formula 1-2 was prepared in substantially the same manner as in Synthesis Example 2 except that 1.6 g of a compound represented by Chemical Formula 1c (trimethyltin styrene, AG029H1L, Angene Chemical) was used instead of the compound represented by Chemical Formula 1b.

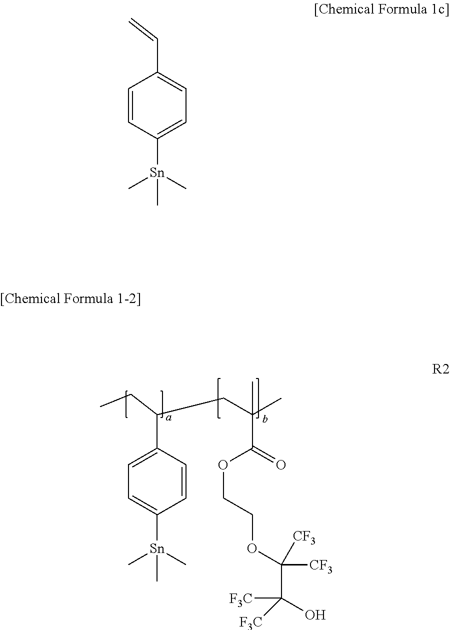

### Synthesis Example 4: Preparation of Polymer R3

A polymer (R3, Mw=6,500, a:b=78:22) having a structure represented by Chemical Formula 1-3 was prepared in substantially the same manner as in Synthesis Example 2 except that 2.1 g of a compound represented by Chemical Formula 1d (dibutyltin maleate, Sigma Aldrich Corp.) was used instead of the compound represented by Chemical Formula 1b.

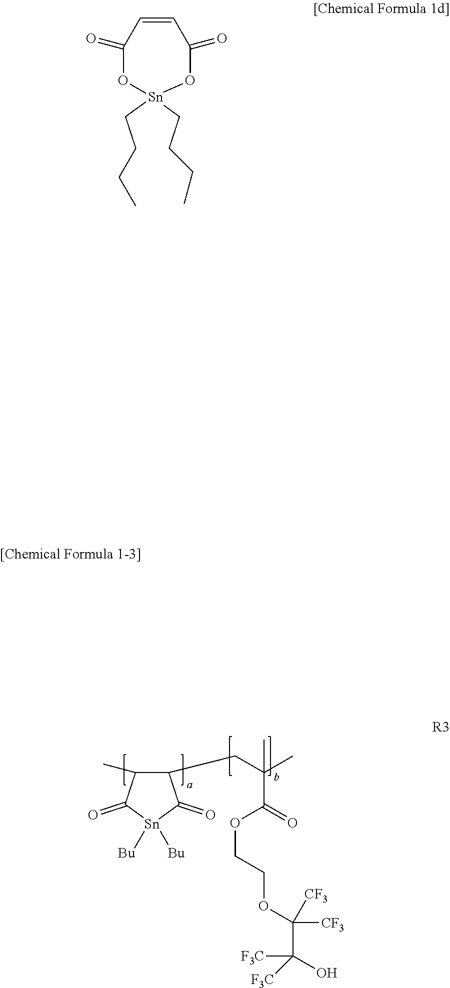

### Synthesis Example 5: Preparation of Polymer R4

A polymer (R4, Mw=5,000, n=100) having a structure represented by Chemical Formula 1-4 was prepared in substantially the same manner as in Synthesis Example 2 except that the compound represented by Chemical Formula 1b was not used.

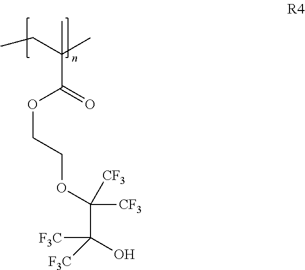

### Preparation of Resist Topcoat Compositions

### Example 1

0.98 g (0.5 wt %) of the polymer (R1) according to Synthesis Example 2 was dissolved in 199 g of a mixed solvent of DIAE/PGME (w/w=97/3) and then, stirred at room temperature (23° C.) for 24 hours and filtered with a TEFLON (tetrafluoroethylene) filter having a pore size of 0.45 μm to prepare a resist topcoat composition.

### Examples 2 and 3 and Comparative Example 1

Each resist topcoat composition was prepared in substantially the same manner as in Example 1 except that the polymer was changed as shown in Table 1.

### Evaluation 1: Solubility Evaluation

Each of the compositions according to Examples 1 to 3 and Comparative Example 1 was stirred for 24 hours and examined with respect to presence or absence of precipitates with naked eyes (e.g., unassisted eyes), and the results are shown in Table 1.

(absence of precipitation−solubility ∘, presence of precipitation−solubility X)

### Evaluation 2: Developability Evaluation

Each of the photoresist topcoat compositions prepared in Examples and Comparative Examples was spin-coated on a silicon substrate and heat-treated at 110° C. on a hot plate for 1 minute, to form an about 5 nm-thick photoresist topcoat. The substrate having a topcoat formed thereon was rinsed with 2.38% tetramethylammonium hydroxide aqueous solution and heat-treated again at 110° C. on the hot plate for 1 minute and then, measured with respect to a thickness change of the topcoat layer, and the results are shown in Table 1.

$$* Residual film after development ( \% ) = [ Topcoat thickness before development ( nm ) - Topcoat thickness after development ( nm ) ] \times 100 / Topcoat thickness before development ( nm )$$

$$( Residual film after development \leq 20 \% - Developability O , Topcoat thickness after development > 20 \% - Developability X )$$

### Evaluation 3: Evaluation of Sensitivity and LWR

After forming a resist underlayer (thickness: 50 Å) and a photoresist thin film for EUV (a thickness: 700 Å) on a 12-inch silicon substrate, each of the photoresist topcoat compositions according to the examples and the comparative examples was spin-coated and then, heat-treated at 110° C. for 1 minute on a hot plate to form about 5 nm-thick topcoats for photoresist.

On the wafer on which the photoresist topcoat film was formed, a line & space pattern was formed in a Focus-Energy Matrix (FEM) format by using an E-Beam equipment (JBX-9300FS, JEOL Inc.). Optimal or improved sensitivity capable of forming a critical dimension (CD) of 50 nm was confirmed utilizing an interpolation method, and the results are shown in Table 1.

After confirming the optimal or improved sensitivity, the line width roughness (LWR) distribution was measured in the corresponding energy shot using Hitatchi's CD-SEM equipment. In order to increase the reliability of the distribution value, the same pattern of 500 points was measured within the shot, and the final average value is shown in Table 1.

TABLE 1

| | | | | Sensitivity | LWR |
|---|---|---|---|---|---|
| | Polymer | Solubility | Developability | (uC/cm²) | (nm) |
| Example 1 | R1 | ∘ | ∘ | 1000 | 3.8 |
| Example 2 | R2 | ∘ | ∘ | 870 | 3.7 |
| Example 3 | R3 | ∘ | ∘ | 950 | 3.9 |
| Comparative | R4 | ∘ | ∘ | 1200 | 4.3 |
| Example 1 | | | | | |

Referring to Table 1, when the resist topcoat composition according to some example embodiments was applied, excellent solubility and developability were not only maintained, but also sensitivity was improved, but pattern degradation was suppressed or reduced, resultantly having an effect of improving LWR.

The resist topcoat composition according to the comparative example exhibited no LWR improvement effect and exhibited deteriorated sensitivity.

In the resist topcoat composition according to the comparative examples, the LWR improvement effect was not observed or the sensitivity was reduced.

Hereinbefore, certain embodiments have been described and illustrated, however, it should be apparent to a person with ordinary skill in the art that the present disclosure is not limited to the embodiments as described, and may be variously modified and transformed without departing from the spirit and scope of the present disclosure.

### DESCRIPTION OF SYMBOLS

1: forming a photoresist layer
2: forming a photoresist topcoat
3: exposing and developing the photoresist layer and the photoresist topcoat to form a resist pattern
30: photoresist topcoat
100: substrate
101: photoresist layer
102b: photoresist pattern

What is claimed is:

1. A resist topcoat composition, comprising:
a polymer comprising a first structural unit and a second structural unit; and
a solvent,
wherein the first structural unit is represented by Chemical Formula M-1, and
the second structural unit comprises a metal element and is derived from a compound having an unsaturated double bond: 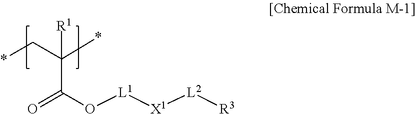
wherein, in Chemical Formula M-1,
R¹ is hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, —O—, —S—, —S(═O)—, —S(═O)₂—, —C(═O)—, —C(═O)O—, —OC(═O), —OC(═O)O—, —NR^{a}—, wherein, R^{a} is hydrogen, deuterium, or a substituted or unsubstituted C1 to C10 alkyl group, or a combination thereof,
R³ is hydrogen, fluorine, a hydroxy group, a substituted or unsubstituted C1 to C20 alkyl group, or a combination thereof,
at least one selected from among R³, L¹ and L² comprises fluorine and a hydroxy group, and
* is a linking point.

2. The resist topcoat composition as claimed in claim 1, wherein:
the first structural unit is represented by Chemical Formula 1: 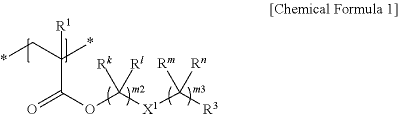
wherein, in Chemical Formula 1,
R¹ is hydrogen or a substituted or unsubstituted C1 to C10 alkyl group,
R^{k}, R^{l}, R^{m}, Rⁿ, and R³ are each independently hydrogen, fluorine, a hydroxy group, a substituted or unsubstituted C1 to C20 alkyl group, or a combination thereof,
m2 and m3 are each independently an integer from 1 to 10,
X¹ is a single bond —O—, —S—, —S(═O)—, —S(═O)₂—, —C(═O)—, —C(═O)O—, —OC(═O), —OC(═O)O—, —NR^{a}— (wherein, R^{a} is hydrogen, deuterium, or a substituted or unsubstituted C1 to C10 alkyl group), or a combination thereof,
at least one selected from among R^{k}, R^{l}, R^{m}, Rⁿ, and R³ comprises fluorine and a hydroxy group.

3. The resist topcoat composition as claimed in claim 1, wherein:
the first structural unit is at least one selected from the group listed in Group I: 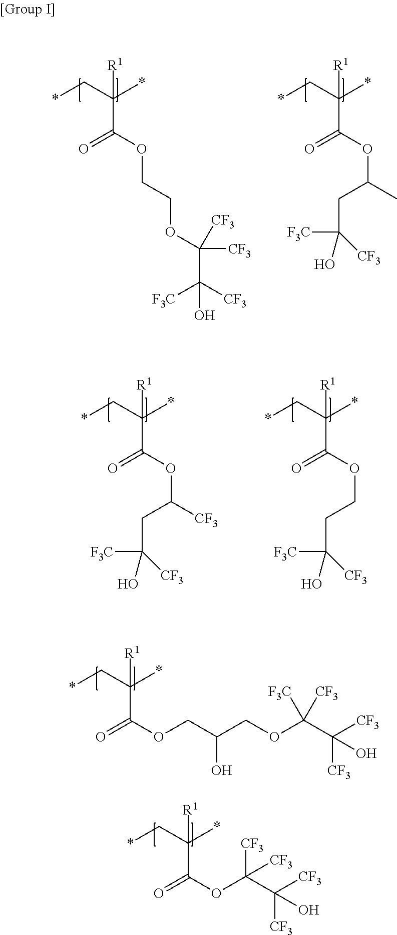
wherein, in Group I,
R¹ are each independently hydrogen or a methyl group, and * is a linking point.

4. The resist topcoat composition as claimed in claim 1, wherein:
the metal element is at least one selected from Sb, Sn, and Te.

5. The resist topcoat composition as claimed in claim 1, wherein:
the second structural unit is derived from a compound represented by Chemical Formula 2 or Chemical Formula 3: 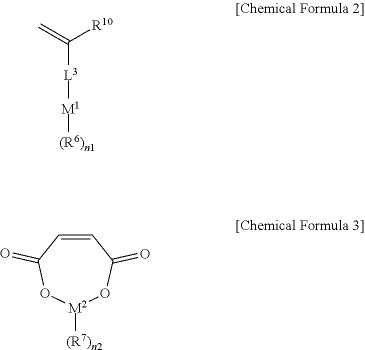
wherein, in Chemical Formula 2 and Chemical Formula 3,
R¹⁰ is hydrogen or a substituted or unsubstituted C1 to C10 alkyl group,
M¹ is Sn, Sb, or Te,
M² is Sn or Sb,
L³ is a single bond, a substituted or unsubstituted C1 to C10 alkylene group, a substituted or unsubstituted C6 to C20 arylene group, or a combination thereof,
R⁶ and R⁷ are each independently a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, a substituted or unsubstituted C6 to C20 aryl group, OR^{b}, or OC(═O)R^{c}, wherein, R^{b} and R^{c} are each independently a substituted or unsubstituted C1 to C10 alkyl group,
n1 is an integer from 1 to 3,
n2 is an integer of 1 or 2,
n2 is an integer of 1 or 2, and
if n1 and n2 are each 2 or greater, each of R⁶ and R⁷ is the same or different from each other.

6. The resist topcoat composition as claimed in claim 1, wherein:
the second structural unit is derived from at least one compound selected from the group listed in Group II:

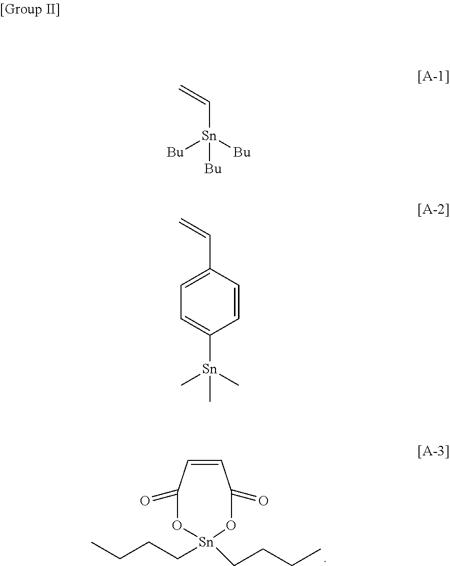

7. The resist topcoat composition as claimed in claim 1, wherein:
the polymer further comprises an additional structural unit represented by Chemical Formula M-2: 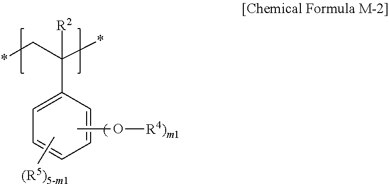
wherein, in Chemical Formula M-2,
R² is hydrogen or a substituted or unsubstituted C1 to C10 alkyl group,
R⁴ is hydrogen, or C(═O)R^{d},
R^{d} is a substituted or unsubstituted C1 to C10 alkyl group,
R⁵ is hydrogen, a halogen, a hydroxy group, a substituted or unsubstituted C1 to C10 alkyl group, or a combination thereof,
m1 is an integer from 1 to 4, and
* is a linking point.

8. The resist topcoat composition as claimed in claim 7, wherein:
the additional structural unit is represented by any one selected from among Chemical Formula 4-1 to Chemical Formula 4-4: 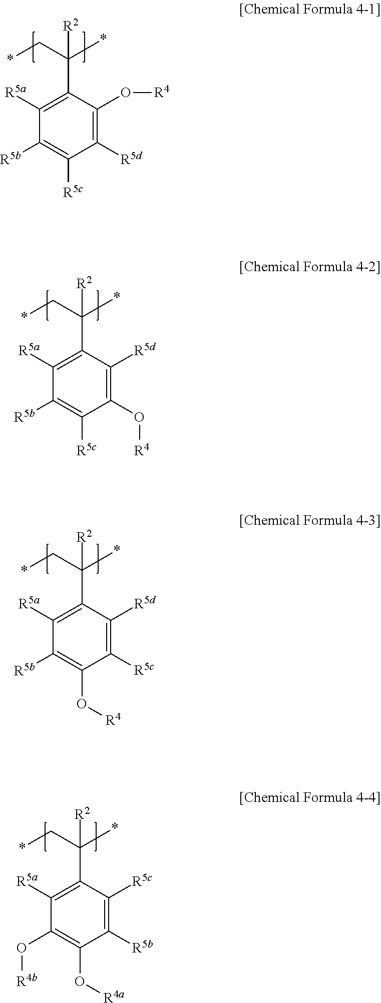
wherein, in Chemical Formula 4-1 to Chemical Formula 4-4,
R² is hydrogen or a methyl group,
R⁴, R^{4a}, and R^{4b} are each independently hydrogen, or C(═O)R^{d},
R^{d} is a substituted or unsubstituted C1 to C5 alkyl group,
R^{5a}, R^{5b}, R^{5c}, and R^{5d} are each independently hydrogen, a halogen, a hydroxy group, a substituted or unsubstituted C1 to C10 alkyl group, or a combination thereof, and
* is a linking point.

9. The resist topcoat composition as claimed in claim 7, wherein:
the additional structural unit is at least one selected from the group listed in Group III: 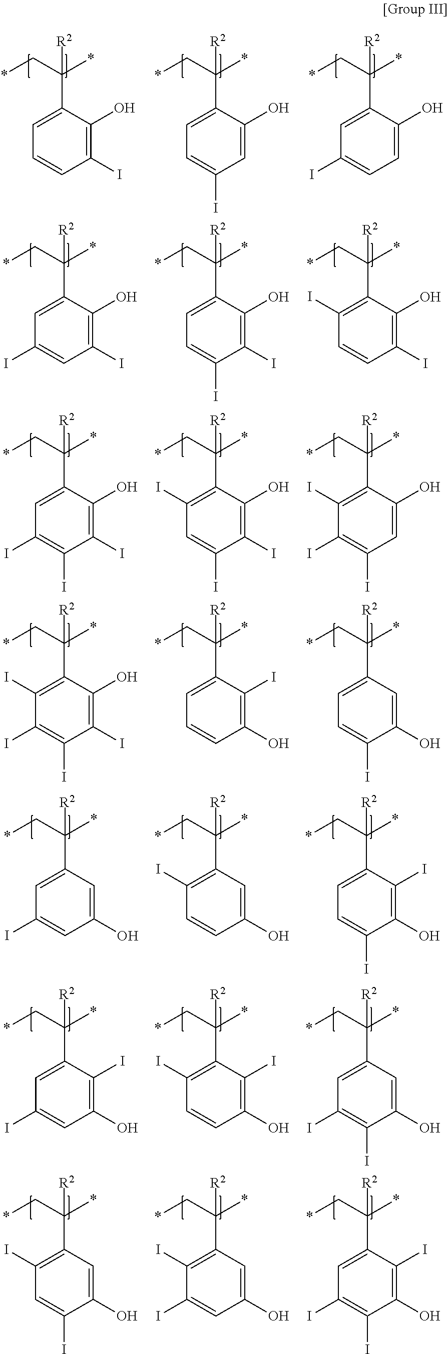 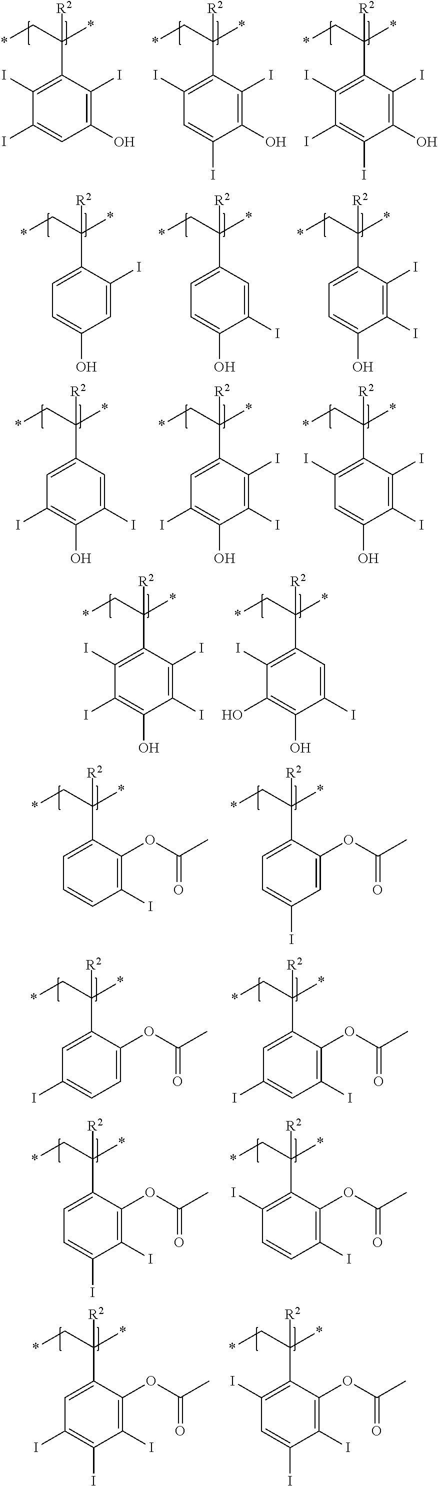 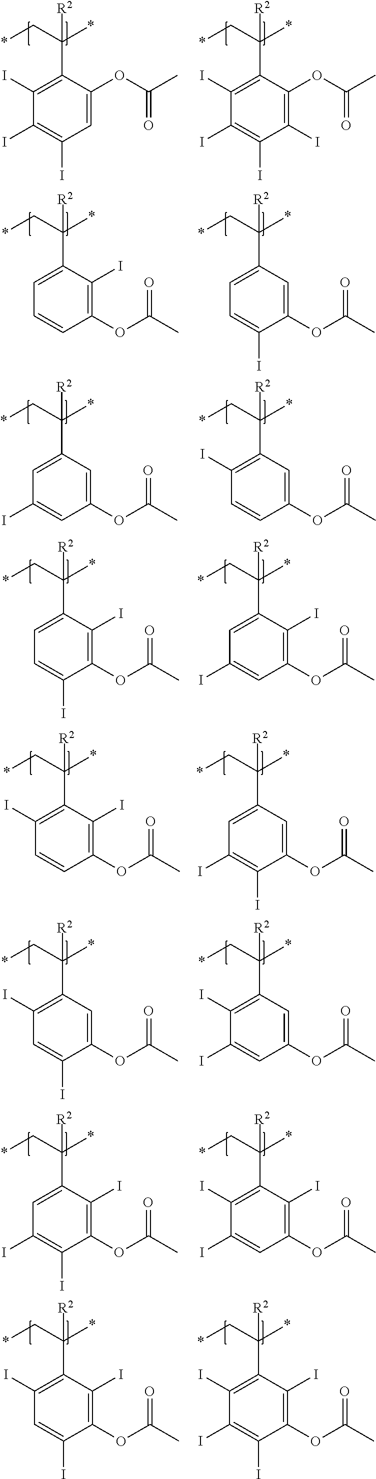 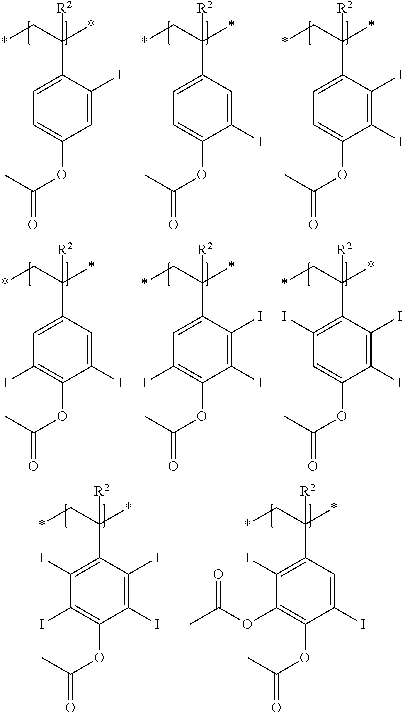
wherein, in Group III,
R² are each independently hydrogen or a methyl group, and * is a linking point.

10. The resist topcoat composition as claimed in claim 1, wherein:
the polymer comprises about 50 to about 99 mol % of the first structural unit and about 1 to about 50 mol % of the second structural unit.

11. The resist topcoat composition as claimed in claim 1, wherein:
the polymer has a weight average molecular weight of about 1,000 g/mol to about 50,000 g/mol.

12. The resist topcoat composition as claimed in claim 1, wherein:
the polymer is included in an amount of about 0.1 wt % to about 10 wt % based on a total weight of the resist topcoat composition.

13. The resist topcoat composition as claimed in claim 1, wherein:
the solvent is an ether solvent.

14. A method of forming patterns, the method comprising:
coating and heating a photoresist composition on a substrate to form a photoresist layer,
coating and heating the resist topcoat composition as claimed in claim 1 on the photoresist layer to form a topcoat, and
exposing and developing the topcoat and the photoresist layer to form a resist pattern.
